(19) United States
(12) Patent Application Publication
(10) Pub. No.: US 2008/0239777 A1
(43) Pub. Date: Oct. 2, 2008

(54) Apparatus for Converting an Electrical Current and Method for Reducing the Load-Change Stress of Power Semiconductor Units in the High-Voltage Energy Distribution and Transmission Sector

(75) Inventor: Jorg Dorn, Buttenheim (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munich (DE)

(21) Appl. No.: 12/093,772

(22) PCT Filed: Nov. 15, 2006
(86) PCT No.: PCT/EP2006/068473

§ 371 Date: May 15, 2008

(30) Foreign Application Priority Data
Nov. 16, 2005 (DE) 10 2005 055 132.7

(51) Int. Cl. H05K 7/20

(52) U.S. Cl. 363/141

(57) ABSTRACT

An apparatus for converting an electrical current in a high-voltage energy distribution and transmission system has one or more current converter valves with a series circuit of a plurality of power semiconductor units. A cooler cools the power semiconductor units. Temperature deviations of the power semiconductor units can be decreased in a cost-effective manner in that the cooler is provided with a control unit that provides cooling in dependence on a current flow via the power semiconductor units.

Apparatus for converting an electric current and method for reducing the load variation load on power semiconductor units in the field of high-voltage power distribution and transmission

The invention relates to an apparatus for converting an electric current in the field of high-voltage power distribution and transmission, having at least one converter valve which has a series circuit comprising power semiconductor units, and having cooling means for cooling the power semiconductor units.

The invention also relates to a method for reducing load variation loads on power semiconductor units in the field of high-voltage power transmission and distribution, in which power semiconductor units which are designed to convert current are cooled by a cooling means.

An apparatus such as this and a method such as this are already known from the familiar prior art. For example, power semiconductor units are used for high-voltage direct-current transmission (HVDC) in the field of power transmission and distribution. A high voltage in the region of several hundred kilovolts results in the power semiconductor units in this case being connected in series from a converter valve, with the converter valve being arranged in a bridge circuit in order to form a converter. The AC voltage side of each converter is connected to an AC power supply system, and the DC voltage side is connected to a further converter. A DC circuit is therefore formed between the converters, allowing energy to be exchanged between the AC voltage power supply system.

Power semiconductor units are also used in so-called flexible AC transmission systems, for example as high-speed electronic switches. The electronic switches are used, for example, to dynamically adjust the impedance of a transmission line.

U.S. Pat. No. 6,714,427 B1 discloses a method in which electrical power is transmitted between two AC voltage power supply systems by means of three-pole high-voltage direct-current transmission. The direct current which occurs in this case flows through three transmission conductors, with the direct current in one of the transmission conductors being above the thermally permissible maximum value for a short time, and with the current flowing in the opposite sense to this being distributed between the two other transmission conductors. After a short time period, the function of the transmission conductors is periodically interchanged, so that the high direct current, which is greater than the maximum permissible limit value, now flows through a line which was previously not loaded so severely. This makes it possible to increase the transmission capacity of a transmission path which was previously used as a three-phase alternating-current line, and in this way to justify the costs of a retrospectively installed high-voltage direct-current transmission system.

In the method according to U.S. Pat. No. 6,714,427, the period duration of current modulation is in the order of magnitude of several minutes. However, this results in a load variation load on the power semiconductor units which is well above the normal design levels for the field of power transmission and distribution.

The expression load variation of power semiconductor units means temperature cycling of the power semiconductors from which the power semiconductor units are formed, as a result of the current load. This temperature cycling results in mechanical loads for example resulting from different thermal expansions, thus reducing the life of the power semiconductors that are used. For this reason, manufacturers of power semiconductors specify the load variation resistance, that is to say the characteristic of the power semiconductor to withstand a specific number of load variations as a function of the temperature change. The load variation load of the power semiconductors used in the field of power distribution in transmission has until now been so low that the life of the power semiconductors was above the specified operating life of the respective installation, with regard to the load variation load.

However, when using a method described in U.S. Pat. No. 6,714,427 B1 for power transmission, the load variation load on the power semiconductor units is increased to such an extent that additional measures are required in order to make it possible to ensure the previously specified installation life requirements in the field of power distribution and transmission.

One method that is known from the prior art consists of keeping the temperature changes or fluctuations low by appropriately derating the power semiconductors in the power semiconductor units, that is to say by making them larger. However, the derating also considerably increases the costs of the respective installation.

The object of the invention is therefore to provide an apparatus and a method of the type mentioned initially by means of which it is possible to cost-effectively reduce the temperature changes in the power semiconductor units.

With regard to the apparatus mentioned above, the invention achieves this object by the cooling means having control means which provide cooling as a function of the current flow through the power semiconductor units.

With regard to the method mentioned initially, the invention achieves this object by the power semiconductor units being cooled as a function of the current flowing through the power semiconductor units.

According to the invention, cooling means and control means are provided which allow the power semiconductor units to be cooled as a function of the current flowing through the power semiconductor units. For example, the cooling power of the cooling means is increased for relatively high current levels while, in contrast, the cooling is reduced for a relatively low current load. This reduces the amplitude of the periodic temperature fluctuation, thus considerably lengthening the life of the power semiconductor units.

For the purposes of the invention, by way of example, individual power semiconductors, for example in the form of disks, may be used as the power semiconductor units. In contrast to this, for the purposes of the invention, a power semiconductor unit is a module which has a plurality of power semiconductors, with the power semiconductors in each module expediently being connected to one another. The modules are arranged connected in series. Each module advantageously has its own energy store.

A converter valve is advantageously provided by connecting the power semiconductor units in series. The apparatus furthermore comprises, for example, a converter which comprises a plurality of converter valves arranged in a bridge circuit. In a further refinement of the invention, the apparatus is a so-called 12-pulse converter, which comprises two 6-pulse circuits connected in series with one another. However, in principle, any converter topology can be used for the purposes of the invention.

In principle, any power semiconductor from the prior art may be used as a power semiconductor for the purposes of the invention, in particular diodes, thyristors, IGBTs or GTOs. The power semiconductors in the power semiconductor units therefore include all power semiconductors which can be switched off.

For the purposes of the invention, by way of example, the cooling means comprise a cooling circuit with a coolant pump and a heat exchanger in which a fluid coolant is circulated.

The cooling means advantageously have a cooling circuit with a heat exchanger and a cooling pump whose pump power can be adjusted by the control means. The control means in this case advantageously comprise current measurement devices which are designed to detect the current flowing through the series circuit. Each current measurement device is connected by a measurement line to a computation unit which, for example, uses software and predetermined internal logic to define a coolant flow rate as well as the voltage and current supplies required for this purpose for the coolant pump, from the current values transmitted from the current measurement device. In contrast to this, the computation unit may, of course, also be in the form of an analog regulator which is designed to process analog current measured values. By way of example, the rotation speed of the coolant pump is controlled. The control means ensure that the coolant pump is driven corresponding to the calculated current and voltage values. In this way, the coolant pump ensures that the power semiconductor units are cooled as a function of the current flowing through the power semiconductor units. The amplitudes of the temperature fluctuations or temperature changes of the power semiconductor units are in this way reduced.

The cooling means expediently have a cooling circuit with a heat exchanger and a coolant pump, with the cooling power of the heat exchanger being adjustable by the control means. In this refinement as well, the control means have current measurement devices and a computation unit or regulation unit. The current measurement devices transmit the current measured values, as determined from the measured currents flowing through the power semiconductor units, to the computation unit. The computation unit uses analog circuitry or, for example, internal logic to determine a current and voltage supply for the heat exchanger, as a function of the current flow through the power semiconductor units. Finally, the control means supply the heat exchanger with current and voltage supplies corresponding to the calculated current and voltage values. By way of example, regulation such as this results in increased cooling power when the current flows through the power semiconductor units are relatively high, thus reducing the temperature of the circulated coolant.

According to a further variant of the invention, the cooling means have a cooling circuit with a heat exchanger, a coolant pump and a controllable throttle valve, whose flow resistance can be adjusted by the control means. In this refinement of the invention as well, the current flowing through the power semiconductor units is first of all determined in a manner known per se, and the measured current values are then made available to a computation unit. The control means then adjust the throttle valve as a function of the measured current, thus varying the flow rate as appropriate for the current flow.

According to one preferred refinement of the invention, the cooling means have a cooling circuit with a heat exchanger, a coolant pump and a multiway valve which can be adjusted by the control means. The multiway valve allows the cooling to be regulated at low cost and at the same time quickly.

According to one further development which is expedient for this purpose, the multiway valve is connected to an associated converter valve or to an associated group of converter valves and to a bypass channel for bridging the converter valve or the group of converter valves. The regulation of the multiway valve allows the control means either to pass the entire flow of the coolant with a high cooling power in consequence through the converter or the respective group of converters. This is the situation, for example, when the converter valve, which comprises the power semiconductor units connected in series, is subject to high currents, with the currents being passed via the power semiconductor units. When the load on the converter valve is less, it is partially bridged by the bypass channel so that the cooling of the power semiconductor units in the converter valve is reduced.

The heat exchanger is advantageously arranged in the bypass channel.

According to a further expedient further development, the multiway valve is connected to a first converter valve or to a first group of converter valves, and to at least one second converter valve or to a second group of converter valves. This means that the control means has access to the multiway valve to control the ratio of the coolant flow through the converter valves that are connected to the multiway valve, or through the group of converter valves, depending on the current load.

According to one further development which is expedient for this purpose, each multiway valve is connected on the input side to the heat exchanger and to the output of at least one converter valve or of at least one group of converter valves, and is connected on the output side to the input of another associated converter valve or to another associated group of converter valves. This makes use of the fact that the temperature of the circulated coolant is higher at the output of a converter valve than the temperature at the input of the converter valve. If a coolant such as this at an increased temperature is used to cool a further converter valve, the cooling power is, of course, reduced for this converter valve. This makes it possible to configure the invention particularly cost-effectively. For the purposes of this further development, one multiway valve can be provided for each converter valve and is included in the cooling circuit in this way. It should be noted that the coolant pump can in principle be arranged as required within the cooling circuit. For example, in this refinement of the invention as well, the coolant pump can be arranged in the flow direction between the heat exchanger and the multiway valve, with the multiway valve nevertheless being connected on the input side to the heat exchanger, for the purposes of the chosen wording. For the purposes of the invention, the wording “connected on the input side to the heat exchanger” means that the circulated coolant can be cooled by the heat exchanger on its way from the output of the multiway valve or valves to the input of the respective multiway valve.

According to one expedient further development of the method, the flow rate of a coolant through a cooling circuit is adjusted by control means as a function of the current flowing through the power semiconductor units. With regard to the design options and the advantages of this further development, reference should be made to the previous statements.

In one modification relating to this, the inlet temperature of the coolant is made dependent on the currents flowing through the power semiconductor units.

Further expedient refinements and advantages of the invention are the subject matter of the following description of exemplary embodiments of the invention, with reference to the figures of the drawing, in which the same reference symbols refer to components having the same effect, and in which:

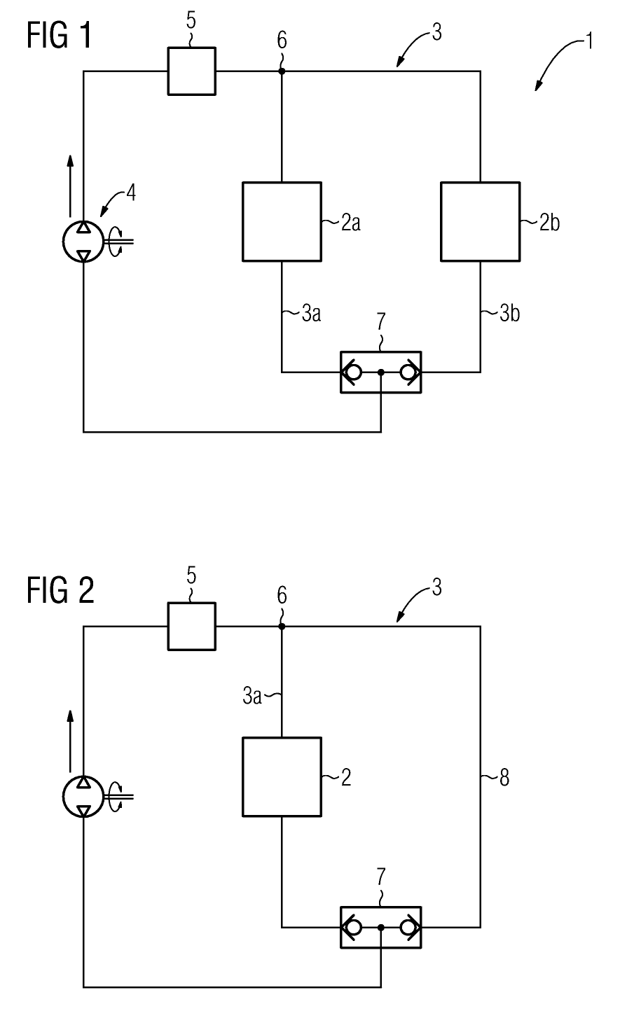

FIG. 1 shows a first exemplary embodiment of the apparatus according to the invention, illustrated schematically,

FIG. 2 shows a further exemplary embodiment of the apparatus according to the invention, illustrated schematically, and

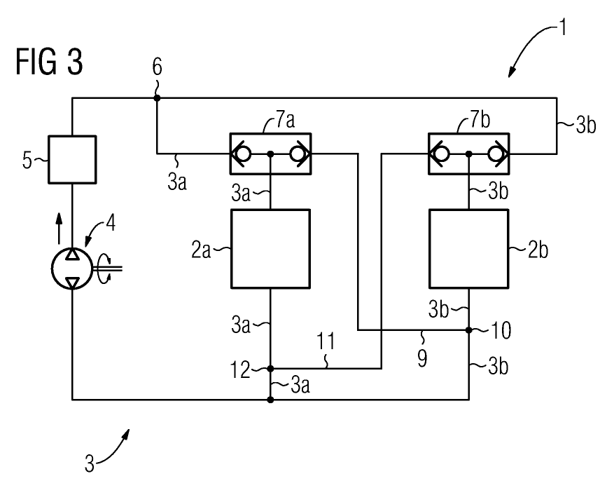

FIG. 3 shows a further exemplary embodiment of the apparatus according to the invention, illustrated schematically.

FIG. 1 shows one exemplary embodiment of the apparatus 1 according to the invention, illustrated schematically. The apparatus has two converters 2a and 2b which are loaded in a manner which fluctuates periodically over time. A cooling circuit 3 is provided in order to cool the power semiconductor units, which are connected to one another in series in order to form converter valves. In the illustrated exemplary embodiment, the power semiconductor units are power semiconductors in the form of disks. The converter valves in the converters 2a and 2b are arranged in a bridge circuit, in the illustrated exemplary embodiment. The cooling circuit 3 expediently has pipelines in which a coolant has circulated. A coolant pump 4 is used for circulation, and has a variable rotation speed in the illustrated exemplary embodiment. However, this is not absolutely essential for the purposes of the invention.

The coolant pump 4 is followed in the flow direction indicated by the arrow that is shown by a heat exchanger 5, adjacent to which there is a junction point 6 in the flow direction. The coolant flow is split between the converter valves 2a and 2b by means of the junction point 6. The converter valves 2a and 2b are in turn followed in the flow direction by a multiway valve 7, which is connected on the input side to the output of the respective converter valve 2a or 2b, and is directly connected on the output side to the coolant pump.

The input-side position of the multiway valve 7 can be regulated by control means, which are not shown in FIG. 1, such that the flow resistance and therefore the flow rate via the converter valves 2a and 2b can be set to the desired level. In this case, the control means regulate the multiway valves 7 such that the flow rate is set as a function of the current flowing through the series-connected power semiconductor units in the converter valves 2a or 2b. In particular, the flow rate of the coolant is increased when the current load on the power semiconductor units is increased.

The control means, which in this case can also be referred to as regulation means, comprise expedient measurement devices for producing four digital current measured values which correspond to the current flowing through the power semiconductor units. However, for the purpose of the invention, the closed-loop control can also be carried out on the basis of analog current measured values. Measurement devices such as these include, for example, current transformers for producing an output channel which is proportional to the current flowing through the power semiconductor units. The output signal from the current transformer is then sampled by a sampling unit, in order to obtain sample values. The sample values are then converted to digital current measured values by an analog/digital converter. The current measured values are transmitted to a computation unit which calculates the position of a stepping motor on the basis of the current measured values and, for example, internal logic, with each position being permanently associated with a flow resistance in a cooling circuit branch 3a or a cooling circuit branch 3b. This allows variation by means of the multiway valve 7 via the flow resistance and the cooling of the converter 2a or 2b.

It should be noted that the control means can be described only on the basis of examples. The flow resistance via the multiway valve can also be regulated by the control means in any other desired manner, which is obvious to a person skilled in the art. For example, it is also possible for the control means to access both the cooling pump and the multiway valve in order to adjust both the pump power and the flow resistance as appropriate to the respective requirements, that is to say as a function of the current flowing through the power semiconductor units.

It is, of course, also possible for the respective reference symbols 2a and 2b to refer to a single series circuit of power semiconductor units, that is to say to a single converter valve, and not to a group of converter valves, which are connected in a known manner forming a converter.

FIG. 2 shows a schematic illustration of a further exemplary embodiment of the invention, with this exemplary embodiment differing from the exemplary embodiment shown in FIG. 1 in that the converter valve 2 or the converter 2, as a group of converter valves, can be breached by a bypass channel 8. For example, the cooling of the converter valve 2 can be completely interrupted by closing the input of the multiway valve 7 which is connected to the converter valve 2. Instead of this, the coolant is passed via the bypass channel 8 in the direction shown by the arrow, in which case that input of the multiway valve 7 which is connected to the bypass channel 8 is then, of course, open.

FIG. 3 shows a further exemplary embodiment of the invention, illustrated schematically. In the illustrated exemplary embodiment, two multiway valves 7a and 7b are arranged upstream in the flow direction of the respectively associated converter valves or converters 2a and 2b, to which they are each connected on the output side via the cooling circuit branch 3a or 3b, respectively. The two multiway valves 7a, 7b are connected on the input side to the distribution point 6, via the cooling circuit branch 3a or 3b, respectively. The multiway valve 7a is also connected via a connecting branch 9 to a junction point 10, and therefore to the output of the converter valve 2b. The multiway valve 7, in contrast, is connected via the connecting branch 11 to the junction point 12, and is therefore connected on the input side to the output of the converter or of the converter valve 2a. The coolant, which is supplied to the respective multiway valves 7a and 7b via the respective connecting branches 9 and 10 has already been used once to cool a converter 2a or 2b, respectively, and for this reason has been heated. The temperature of the coolant at the output of the respective multiway valve 7a or 7b can therefore be selected within a mixing range, which is defined on the input side. For example, if the multiway valve 7a opens the input connected to the connecting line 9 while, in contrast, the input connected to the cooling circuit branch 3a remains closed, a higher temperature can be set at the output of the multiway valve 7a than will be possible in the opposite case.

Finally, it should be noted that the coolant flow, for example in exemplary embodiments illustrated in FIG. 1, can be switched on and off alternately, as well, by means of the multiway valve 7. In other words, that input of the multiway valve 7 which is connected to the cooling circuit branch 3a can be opened completely for a specific time period, while that input which is connected to the coolant circuit branch 3b is completely closed. Once the defined time period has elapsed, the opposite situation occurs.

1-11. (canceled)

12. In a high-voltage power distribution and transmission system, an apparatus for converting an electric current, comprising:
at least one converter valve having a series circuit of power semiconductor units; and
cooling means for cooling said power semiconductor units, said cooling means having control means for cooling said power semiconductor units in dependence on a current flow through said power semiconductor units.

13. The apparatus according to claim 12, wherein said cooling means comprise a cooling circuit with a heat exchanger and a coolant pump, and said control means is configured to adjust a pump power of said coolant pump.

14. The apparatus according to claim 12, wherein said cooling means comprise a cooling circuit with a heat exchanger and a coolant pump, and said control means is configured to adjust a cooling power of said heat exchanger.

15. The apparatus according to claim 12, wherein said cooling means comprise a cooling circuit with a heat exchanger, a coolant pump, and a controllable throttle valve, and wherein said control means is configured to adjust a flow resistance of said throttle valve.

16. The apparatus according to claim 12, wherein said cooling means comprise a cooling circuit with a heat exchanger, a coolant pump, and at least one multiway valve, and wherein said control means is configured to adjust said multiway valve.

17. The apparatus according to claim 16, wherein said multiway valve is connected to an associated said converter valve and/or to an associated group of said converter valves and to a bypass channel for bridging said converter valve or said group of converter valves.

18. The apparatus according to claim 16, wherein said at least one converter valve is one of a plurality of converter valves, said multiway valve is connected to a first said converter valve or to a first group of said converter valves, and said multiway valve has an input side connected to at least one second said converter valve or to a second group of said converter valves.

19. The apparatus according to claim 18, wherein each multiway valve is connected on the input side to said heat exchanger and to an output of at least one said converter valve or of at least one group of said converter valves, and is connected on the output side to an input of another associated said converter valve or to another associated group of said converter valves.

20. In a high-voltage power distribution and transmission system, a method for reducing load variation loads on power semiconductor units, the method which comprises:
conducting currents and converting the currents with the power semiconductor units; and
cooling the power semiconductor units with cooling means as a function of the current flowing through the power semiconductor units.

21. The method according to claim 20, which comprises adjusting a flow rate of a coolant through a cooling circuit by way of control means as a function of the current flowing through the power semiconductor units.

22. The method according to claim 20, which comprises adjusting an inlet temperature of a coolant as a function of the current flowing through the power semiconductor units.
